(19) United States
(12) Patent Application Publication
(10) Pub. No.: US 2022/0199863 A1
(43) Pub. Date: Jun. 23, 2022

(54) LIGHT EMITTING ELEMENT, METHOD OF MANUFACTURING THE SAME, AND DISPLAY DEVICE INCLUDING THE SAME

(71) Applicant: Samsung Display Co., LTD., Yongin-si (KR)

(72) Inventors: Se Hun KIM, Yongin-si (KR); Chang Hee LEE, Yongin-si (KR); Yun Hyuk KO, Yongin-si (KR); Jun Bo SIM, Yongin-si (KR); Jae Kook HA, Yongin-si (KR); Dong Uk KIM, Yongin-si (KR); In Pyo KIM, Yongin-si (KR); Je Won YOO, Yongin-si (KR); Hyun Min CHO, Yongin-si (KR); Chan Woo JOO, Yongin-si (KR); Na Mi HONG, Yongin-si (KR)

(73) Assignee: Samsung Display Co., LTD., Yongin-si (KR)

(21) Appl. No.: 17/513,302

(22) Filed: Oct. 28, 2021

(30) Foreign Application Priority Data
Dec. 21, 2020 (KR) 10-2020-0180051

(51) Int. Cl. H01L 33/44; H01L 27/15; H01L 33/00; H01L 33/24

(52) U.S. Cl. CPC H01L 33/44; H01L 27/156; H01L 2933/0025; H01L 33/0093; H01L 33/24; H01L 33/007

(57) ABSTRACT

A method for manufacturing a light emitting element includes forming a first semiconductor layer on a substrate, the first semiconductor layer including a semiconductor of a first type; forming an active layer on the first semiconductor layer; forming a second semiconductor layer on the active layer, the second semiconductor layer including a semiconductor of a second type different from the first type; performing an etching process of removing at least a portion of each of the first semiconductor layer, the active layer, and the second semiconductor layer in a direction toward the first semiconductor layer from the second semiconductor layer; and forming a first insulating layer to surround an outer surface of the active layer. The first insulating layer is formed by a wet process.

### CROSS-REFERENCE TO RELATED APPLICATION

The application claims priority to and the benefit of Korean patent application 10-2020-0180051 under 35 U.S.C. § 119(a), filed on Dec. 21, 2020 in the Korean Intellectual Property Office (KIPO), the entire disclosure of which is incorporated herein by reference.

### BACKGROUND

### 1.Technical Field

The disclosure generally relates to a manufacturing method for a light emitting element, a light emitting element manufactured using the same, and a display device including the same.

### 2. Description of the Related Art

Recently, as interest in information displays is increased, research and development of display devices have been continuously conducted.

### SUMMARY

Embodiments provide a manufacturing method for a light emitting element, a light emitting element manufactured using the same, and a display device including the same, which can reduce process cost and decrease process performance time.

In accordance with an aspect of the disclosure, there is provided a method for manufacturing a light emitting element, the method including forming a first semiconductor layer on a substrate, the first semiconductor layer including a semiconductor of a first type; forming an active layer on the first semiconductor layer; forming a second semiconductor layer on the active layer, the second semiconductor layer including a semiconductor of a second type different from the first type; performing an etching process of removing at least a portion of each of the first semiconductor layer, the active layer, and the second semiconductor layer in a direction toward the first semiconductor layer from the second semiconductor layer; and forming a first insulating layer to surround an outer surface of the active layer. The first insulating layer may be formed through a wet process.

The performing of the etching process may include forming a light emitting structure to include the first semiconductor layer, the active layer disposed on the first semiconductor layer, and the second semiconductor layer disposed on the active layer.

The method may further include forming a sacrificial layer on the substrate, after the preparing of the substrate.

The method may further include forming a second insulating layer on the first insulating layer.

The second insulating layer may be formed by a wet process.

The second insulating layer may be formed by a dry process.

The method may include forming a second insulating layer on the active layer by a dry process, before the forming of the first insulating layer.

The wet process may be at least one of a sol-gel process, a dip coating process, and an electrochemical deposition process.

The dry process may be any one of Atomic Layer Deposition (ALD), Physical Vapor Deposition (PVD), Chemical Vapor Deposition (CVD), and Plasma Enhanced Chemical Vapor Deposition (PECVD).

The first insulating layer may include at least one of silicon oxide (SiOₓ), silicon nitride (SiNₓ), silicon oxynitride (SiON), aluminum oxide (AlOₓ), and titanium oxide (TiOₓ).

The second insulating layer may include at least one of silicon oxide (SiOₓ), silicon nitride (SiNₓ), silicon oxynitride (SiON), aluminum oxide (AlOₓ), and titanium oxide (TiOₓ).

The first insulating layer may have a thickness in a range of about 5 nm to about 200 nm.

The first insulating layer may have a thickness in a range of about 35 nm to about 45 nm.

The second insulating layer may have a thickness in a range of about 35 nm to about 45 nm.

In accordance with another aspect of the disclosure, there is provided a light emitting element including a substrate; a first semiconductor layer disposed on the substrate and including a semiconductor of a first type; an active layer disposed on the first semiconductor layer; a second semiconductor layer disposed on the active layer and including a semiconductor of a second type different from the first type; a first insulating layer surrounding an outer surface of the active layer and formed by using a wet process; and forming a second insulating layer on the first insulating layer and formed by using a wet process. At least a portion of each of the first semiconductor layer, the active layer, and the second semiconductor layer is removed by an etching process in a direction toward the first semiconductor layer from the second semiconductor layer.

The first insulating layer may include silicon oxide (SiOₓ), and the second insulating layer may include aluminum oxide (AlOₓ).

The first insulating layer may have a thickness in a range of about 35 nm to about 45 nm, and the second insulating layer may have a thickness in a range of about 35 nm to about 45 nm.

In accordance with still another aspect of the disclosure, there is provided a display device including a light emitting element manufactured by using a method for manufacturing the light emitting element.

In accordance with still another aspect of the disclosure, there is provided a light emitting element including: a first semiconductor layer including a semiconductor of a first type; a second semiconductor layer including a semiconductor of a second type different from the first type; an active layer disposed between the first semiconductor layer and the second semiconductor layer; and a first insulating layer surrounding an outer surface of at least the active layer. The first insulating layer includes at least one of silicon oxide (SiOₓ) and aluminum oxide (AlOₓ).

The light emitting element may further include a second insulating layer arranged on the first insulating layer, the second insulating layer surrounding the outer surface of the active layer. The second insulating layer may include at least one of silicon oxide (SiOₓ) and aluminum oxide (AlOₓ).

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIGS. 1 and 2 are perspective and cross-sectional views schematically illustrating a light emitting element in accordance with an embodiment of the disclosure.

FIGS. 3 to 10 are process cross-sectional views schematically illustrating a manufacturing method for the light emitting element in accordance with an embodiment of the disclosure.

FIG. 11 is a plan view schematically illustrating a display device including the light emitting element in accordance with an embodiment of the disclosure.

FIG. 12 is a schematic cross-sectional view taken along line I-I′ shown in FIG. 11.

### DETAILED DESCRIPTION OF THE EMBODIMENTS

Some embodiments disclosed in the specification are provided only for illustrative purposes and for full understanding of the scope of the disclosure by those skilled in the art. However, the disclosure is not limited to the embodiments, and it should be understood that the disclosure includes modification examples or change examples without departing from the spirit and scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

The phrase “at least one of” is intended to include the meaning of “at least one selected from the group of” for the purpose of its meaning and interpretation. For example, “at least one of A and B” may be understood to mean “A, B, or A and B.”

The drawings attached to the specification are provided to easily explain the disclosure, and the shapes shown in the drawings may be exaggerated and displayed as necessary to help understanding of the disclosure, and thus the disclosure is not limited to the drawings.

In the specification, when it is determined that a detailed description of a known configuration or function related to the disclosure may obscure the gist of the disclosure, a detailed description thereof will be omitted as necessary.

The disclosure generally relates to a light emitting element, a manufacturing method for the light emitting element, and a display device including the light emitting element.

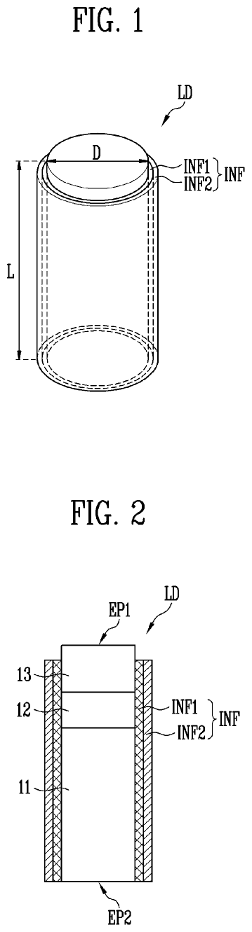

Hereinafter, a light emitting element, a manufacturing method for the light emitting element, and a display device including the light emitting element in accordance with an embodiment of the disclosure will be described with reference to FIGS. 1 to 12.

FIGS. 1 and 2 are schematic perspective and cross-sectional views illustrating a light emitting element in accordance with an embodiment. Although FIGS. 1 and 2 illustrates a pillar-shaped (or columnar-shaped) light emitting element LD, the kind and/or shape of the light emitting element LD is not limited thereto.

Referring to FIGS. 1 and 2, the light emitting element LD includes a first semiconductor layer 11, a second semiconductor layer 13, and an active layer 12 interposed between the first semiconductor layer 11 and the second semiconductor layer 13. In an example, when assuming that an extending direction of the light emitting element LD is a length direction (L), the light emitting element LD may include the first semiconductor layer 11, the active layer 12, and the second semiconductor layer 13, which are sequentially stacked in the length direction (L).

The light emitting element LD may be provided in a columnar shape extending in a direction. The light emitting element LD may have a first end portion EP1 and a second end portion EP2. One of the first and second semiconductor layers 11 and 13 may be disposed at the first end portion EP1 of the light emitting element LD. The other of the first and second semiconductor layers 11 and 13 may be disposed at the second end portion EP2 of the light emitting element LD.

In some embodiments, the light emitting element LD may be a light emitting element manufactured in a columnar shape by an etching process or the like. In this specification, the term “columnar shape” may include a rod-like shape or bar-like shape, which is long in the length direction (L) (for example, having an aspect ratio greater than 1), such as a cylinder or a polyprism, and the shape of a cross section thereof is not particularly limited. For example, a length L of the light emitting element LD may be greater than a diameter D (or a width of the cross-section) of the light emitting element LD.

The light emitting element LD may have a small size to a degree of the nanometer scale to micrometer scale. In an example, the light emitting element LD may have a diameter D (or width) in a range of the nanometer scale to micrometer scale and/or a length L in a range of the nanometer scale to micrometer scale. However, the size of the light emitting element LD is not limited thereto. The size of the light emitting element LD may be variously changed according to design conditions of various types of devices, e.g., a display device, and the like, which use, as a light source, a light emitting device using the light emitting element LD.

The first semiconductor layer 11 may be a first conductivity type semiconductor layer. For example, the first semiconductor layer 11 may include an N-type semiconductor layer. In an example, the first semiconductor layer 11 may include a semiconductor material, e.g., at least one of InAlGaN, GaN, AlGaN, InGaN, A1N, and InN and include an N-type semiconductor layer doped with a first conductivity type dopant such as Si, Ge, or Sn. However, a material constituting the first semiconductor layer 11 is not limited thereto. The first semiconductor layer 11 may be configured with (or formed of) various materials.

The active layer 12 is formed on the first semiconductor layer 11 and may be formed in a single-quantum well structure or a multi-quantum well structure. The position of the active layer 12 may be variously changed according to a kind of the light emitting element LD.

A clad layer (not shown) doped with a conductive dopant may be formed on the top and/or bottom of the active layer 12. In an example, the clad layer may be formed as an AlGaN or InAlGaN layer. In some embodiments, a material such as AlGaN or AlInGaN may be used to form the active layer 12. The active layer 12 may be formed of various materials.

The second semiconductor layer 13 is formed on the active layer 12 and may include a semiconductor layer having a type different from that of the first semiconductor layer 11. For example, the second semiconductor layer 13 may include a P-type semiconductor layer. In an example, the second semiconductor layer 13 may include at least one semiconductor material among InAlGaN, GaN, AlGaN, InGaN, A1N, and InN and include a P-type semiconductor layer doped with a second conductivity type dopant such as Mg. However, a material constituting the second semiconductor layer 13 is not limited thereto. The second semiconductor layer 13 may be formed of various materials.

In case that a threshold voltage or more is applied to two ends (or both ends or end portions) of the light emitting element LD, the light emitting element LD emits light as electron-hole pairs are combined in the active layer 12. The light emission of the light emitting element LD is controlled by using such a principle, so that the light emitting element LD can be used as a light source for various light emitting devices, including a pixel of a display device.

The light emitting element LD may further include an insulating film INF. The insulating film INF may be formed on a surface of the light emitting element LD to at least surround an outer surface of the active layer 12. The insulating film INF may further surround an area of each of the first and second semiconductor layers 11 and 13.

In some embodiments, the insulating film INF may expose both the end portions of the light emitting element LD. For example, the insulating film INF may expose an end of each of the first and second semiconductor layers 11 and 13 respectively located at the first and second end portions EP1 and EP2 of the light emitting element LD. In an embodiment, the insulating film INF may expose a side portion of each of the first and second semiconductor layers 11 and 13 respectively adjacent to the first and second end portions EP1 and EP2 of the light emitting element LD, which have different polarities.

In some embodiments, the insulating film INF may include at least one insulating material among silicon oxide (SiOₓ), silicon nitride (SiNₓ), silicon oxynitride (SiON), aluminum oxide (A1Oₓ), and titanium oxide (TiOₓ). However, a material included in the insulating film INF is not limited to the above-described material.

In case that the insulating film INF covers (or overlaps) the surface of the light emitting element LD, particularly, the outer surface of the active layer 12, the active layer 12 can ensure the electrical stability of the light emitting element LD.

In case that the insulating film INF is provided on the surface of the light emitting element LD, a surface defect of the light emitting element LD may be minimized, thereby improving the lifetime and efficiency of the light emitting element LD. An unwanted short circuit can be prevented from occurring between light emitting elements LD even in case that the light emitting elements LD are disposed close to each other.

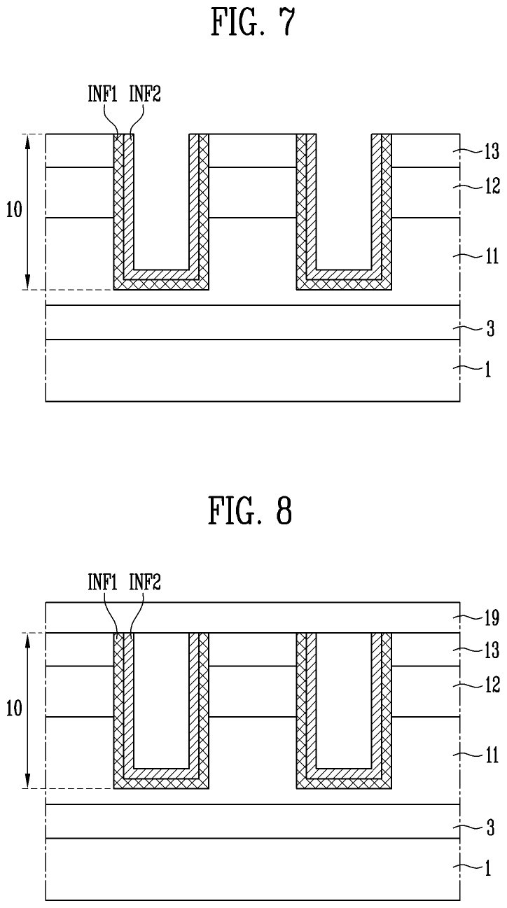

The insulating film INF may be configured with a single film or two or more films. In case that the insulating film INF is configured with a single film, the insulating film INF may be formed by a wet process. In case that the insulating film INF is configured with two or more films, at least one of the films included in the insulating film INF may be formed by a wet process. This will be described in detail below with reference to FIGS. 6 and 7, and thus repetitive descriptions thereof will be omitted.

For convenience of description, the insulating film INF including two films will hereinafter be described.

The insulating film INF may include a first insulating film INF1 and a second insulating film INF2. The first insulating film INF1 may surround the outer surface of the active layer 12, and the second insulating film INF2 may surround an outer surface of the first insulating film INF1. For example, a portion of the first insulating film INF1 may be located between the active layer 12 and the second insulating film INF2. Another portion of the first insulating film INF1 may be located between the first semiconductor layer 11 or the second semiconductor layer 13 and the second insulating film INF2.

In an embodiment, the light emitting element LD may further include an additional component in addition to the first semiconductor layer 11, the active layer 12, the second semiconductor layer 13, and/or the first and second insulating films INF1 and INF2 surrounding the same. For example, the light emitting element LD may additionally include at least one phosphor layer, at least one active layer, at least one semiconductor layer, and/or at least one electrode layer, which are disposed at one ends (or first ends) of the first semiconductor layer 11, the active layer 12, and/or the second semiconductor layer 13. In an example, a contact electrode layer may be disposed at each of the first and second end portions EP1 and EP2 of the light emitting element LD. Although FIGS. 1 and 2 illustrate the pillar-shaped light emitting element LD, the kind, structure, and/or shape of the light emitting element LD may be variously changed. For example, the light emitting element LD may be formed in a core-shell structure having a polypyramid shape.

A light emitting device including the above-described light emitting element LD may be used in various kinds of devices, which require a light source, including a display device. For example, light emitting elements LD may be disposed in each pixel of a display panel and be used as a light source of each pixel. However, the application field of the light emitting element LD is not limited to the above-described example. For example, the light emitting element LD may be used in other types of devices that require a light source, such as a lighting device.

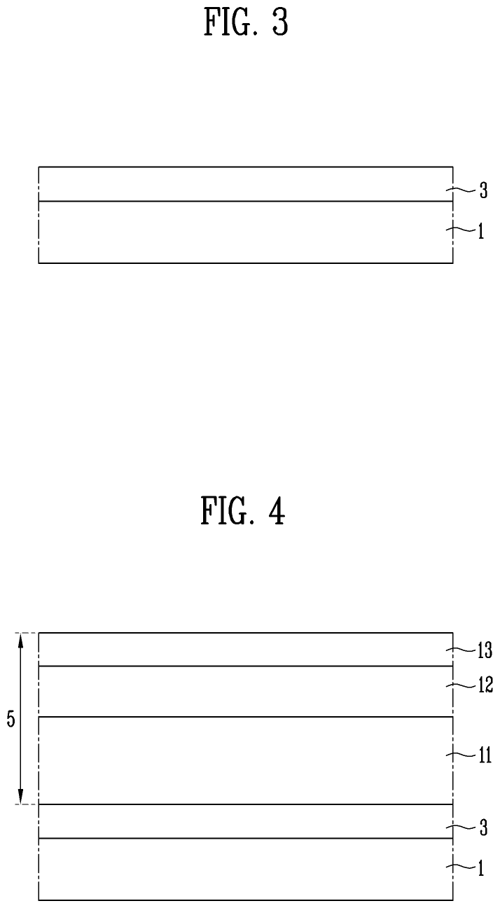

Hereinafter, a manufacturing method for the light emitting element in accordance with an embodiment will be described in detail with reference to FIGS. 3 to 10.

FIGS. 3 to 10 are cross-sectional views schematically illustrating process operations of a manufacturing method for the light emitting element in accordance with an embodiment.

Referring to FIG. 3, a substrate (or stack substrate) 1 may be prepared, and a sacrificial layer 3 may be formed on the stack substrate 1.

The stack substrate 1 may be a base substrate for stacking a target material. The stack substrate 1 may be a wafer for epitaxial growth of a predetermined material. In an example, the stack substrate 1 may be at least one of a sapphire substrate, a GaAs substrate, a Ga substrate, and an InP substrate, but the disclosure is not limited thereto. For example, in case that a specific material satisfies a selectivity for manufacturing the light emitting element LD, and the epitaxial growth of the predetermined material is smoothly performed, the specific material may be selected as a material of the stack substrate 1. A surface of the stack substrate 1 may be flat. The shape of the stack substrate 1 may be a polygonal shape including a rectangular shape or a circular shape, but the disclosure is not limited thereto.

The sacrificial layer 3 may be provided on the stack substrate 1. The sacrificial layer 3 may allow the light emitting element LD and the stack substrate 1 to be physically spaced apart from each other, while the light emitting element LD is manufactured. The sacrificial layer 3 may include at least one of GaAs, AlAs, and AlGaAs. The sacrificial layer 3 may be formed by at least one process among a metalorganic chemical vapor deposition (MOCVD) process, a molecular beam epitaxy (MBE) process, a vapor phase epitaxy (VPE) process, and a liquid phase epitaxy (LPE) process. However, the process of forming the sacrificial layer 3 on the stack substrate 1 may be omitted according to selection of a manufacturing process of the light emitting element LD.

Referring to FIG. 4, a first semiconductor layer 11 may be formed on the sacrificial layer 3, an active layer 12 may be formed on the first semiconductor layer 11, and a second semiconductor layer 13 may be formed on the active layer 12. Similar to the sacrificial layer 3, the first semiconductor layer 11 may be formed by epitaxial growth. The first semiconductor layer 11 may be formed by at least one of the processes listed as the process of forming the sacrificial layer 3. Although not shown in the drawing, an additional semiconductor layer for improving the crystallinity of the first semiconductor layer 11 may be provided between the sacrificial layer 3 and the first semiconductor layer 11. The active layer 12 may emit light having a wavelength of about 400 nmto about 900 nm. The second semiconductor layer 13 may be configured as a semiconductor layer having at least a type different from that of the first semiconductor layer 11. Thus, the active layer 12 is located between the first semiconductor layer 11 and the second semiconductor layer 13, which have different polarities, so that light can be emitted from the active layer 12 when electrical information having a predetermined voltage or higher is provided at both ends of the light emitting element LD.

As described above, the first semiconductor layer 11, the active layer 12, and the second semiconductor layer 13, which are sequentially stacked on the stack substrate 1 and the sacrificial layer 3, may form (or constitute) a light emitting stack structure 5.

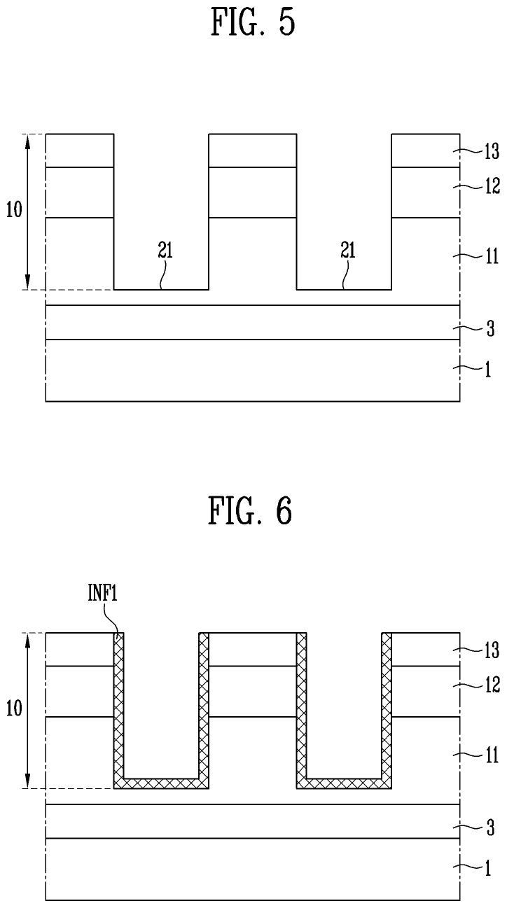

Referring to FIG. 5, a light emitting stack pattern (or light emitting structure) 10 may be formed by etching the light emitting stack structure 5 in a stacking direction. The light emitting stack pattern 10 may correspond to a range (or area) in which the light emitting stack structure 5 is etched and removed in the stacking direction, and may mean a structure in which the first semiconductor layer 11, the active layer 12, and the second semiconductor layer 13 are sequentially arranged each other. The stacking direction may mean a direction perpendicular to a main surface of the stack substrate 1.

In order to form the light emitting stack pattern 10, a mask (not shown) may be disposed on the entire surface of the light emitting stack structure 5, and patterning may be performed at a distance of the nanometer scale or micrometer scale by performing an etching process on the light emitting stack structure 5. In order to perform the etching process on the light emitting stack structure 5, an etching mask pattern having a periodically formed pattern in a plan view may be formed. Subsequently, the light emitting stack structure 5 may be etched in the stacking direction by using the formed etching mask pattern, and thus the light emitting stack pattern 10 may be provided when the etching process is performed. In case that the etching process is performed, at least a portion of the light emitting stack structure 5 may be removed. Therefore, a groove region 21 may be provided, and at least a portion of the first semiconductor layer 11 may be exposed to the outside in the groove region 21.

A dry etching process may be applied to the etching process for forming the light emitting stack pattern 10. In an example, the dry etching process may be at least one of reactive ion etching (RIE), reactive ion beam etching (RIBE), and inductively coupled plasma reactive ion etching (CIP-RIE), but the disclosure is not limited thereto. Unlike a wet etching process, the dry etching process facilitates implementation of unidirectional etching and may be suitable for forming the light emitting stack pattern 10.

After the etching process for forming the light emitting stack pattern 10, a residue (not shown) remaining on the light emitting stack pattern 10 may be removed by an ordinary removal process. The residue may include an etching mask, an insulating material, and the like, which are required in a mask process. In accordance with an embodiment, after the etching process for forming the light emitting stack pattern 10, a process of removing a damaged surface of the light emitting stack pattern 10 may be performed. For example, a wet etching process of removing at least a portion of the damaged surface of the light emitting stack pattern 10 may be performed. The wet etching process may be performed with a KOH solution for five minutes to 20 minutes. The wet etching process is performed on the damaged surface of the light emitting stack pattern 10, so that an impurity formed on the surface of the light emitting stack pattern 10 can be removed.

Referring to FIGS. 6 and 7, a first insulating film INF1 may be formed on the first semiconductor layer 11, the active layer 12, and the second semiconductor 13, which are exposed to the outside. A second insulating film INF2 may be formed on the first insulating film INF1.

The first insulating film INF1 and the second insulating film INF2 may cover (or overlap) at least a portion of each of the first semiconductor layer 11, the active layer 12, and the second semiconductor 13. The first insulating film INF1 and the second insulating film INF2 are formed, so that the first semiconductor layer 11, the active layer 12, and the second semiconductor 13 can be protected from an external influence.

The first insulating film INF1 may have a thickness of about 5 nm to about 200 nm. As another example, the first insulating film INF1 may have a thickness of about 30 nm to about 150 nm. As another example, the first insulating film INF1 may have a thickness of about 35 nm to about 45 nm.

The second insulating film INF2 may have a thickness of about 5 nm to about 200 nm. As another example, the second insulating film INF2 may have a thickness of about 30 nm to about 150 nm. As another example, the second insulating film INF2 may have a thickness of about 35 nm to about 45 nm.

At least one of the first insulating film INF1 and the second insulating film INF2 may be formed by a wet process. The wet process may mean a deposition process accompanied with a chemical reaction. For example, the wet process may mean a process in which, when a predetermined material is to be provided on a target layer on which the predetermined material is to be deposited (or coated), a chemical reaction by which the predetermined material can be acquired is performed on the target layer.

In accordance with an embodiment, each of the first insulating film INF1 and the second insulating film INF2 may be provided by the wet process. The first insulating film INF1 may be formed on the light emitting stack pattern 10 by the wet process, and the second insulating film INF2 may also be formed on the first insulating film INF1 by the wet process.

As another example, the first insulating film INF1 may be formed by the wet process, and the second insulating film INF2 may be formed by a dry process. The first insulating film INF1 may be formed on the light emitting stack pattern 10 by the wet process, and the second insulating film INF2 may be formed on the first insulating film INF1 by the dry process.

As another example, the first insulating film INF1 may be formed by the dry process, and the second insulating film INF2 may be formed by the wet process. The first insulating film INF1 may be formed on the light emitting stack pattern 10 by the dry process, and the second insulating film INF2 may be formed on the first insulating film INF1 by the wet process.

In an example, the wet process may include a sol-gel process, a dip coating process, an electrochemical deposition process, and the like, but the disclosure is not limited to the above-described example. The dry process may include atomic layer deposition (ALD), physical vapor deposition (PVD), chemical vapor deposition (CVD), and plasma enhanced chemical vapor deposition (PECVD), but the disclosure is not limited to the above-described example.

Hereinafter, an example of forming the above-described first insulating film INF1 will be described in more detail with reference to FIG. 6. As described above, the first insulating film INF1 may include at least one of silicon oxide (SiOₓ), silicon nitride (SiNₓ), silicon oxynitride (SiOₓN_{y}), aluminum oxide (A1Oₓ), and titanium oxide (TiOₓ). In an embodiment, an example of forming the first insulating film INF1 including SiO₂ by the wet process and an example of forming the first insulating film INF1 including A1₂O₃ by the wet process will be described.

First, in order to form the first insulating film INF1 including SiO₂ as an example of the above-described silicon oxide (SiOₓ), a light emitting element substrate on which the light emitting stack pattern 10 is formed may be located in a container. The light emitting element substrate may mean a structure including the stack substrate 1, the sacrificial layer 3 formed on the stack substrate 1, and the light emitting stack pattern 10 formed on the sacrificial layer 3. The container may be a beaker, and a liquid-phase solution in which EtOH and deionized water are mixed may be provided as an example in the container. Subsequently, cetyl trimethyl ammonium bromide (CTAB) is added by about 0.16 wt %, and the CTAB is dispersed in the liquid-phase solution in which the light emitting element substrate is provided, by using an agitator for 5 minutes. After the CTAB is dispersed, a precursor provided as the first insulating film INF1 and a catalyst for a reaction of forming the precursor are provided. In an example, the precursor is tetraethyl orthosilicate (TEOS) and may be provided by about 0.5 wt %. The catalyst is NH₃OH and may be provided by about 0.25 wt %. Subsequently, a liquid-phase mixture in which the precursor and the catalyst are proved is stirred by the agitator. The light emitting element substrate is cleansed, and a dry process is performed on the light emitting element substrate at room temperature. In an example, the cleansing of the light emitting element substrate may be performed by using EtOH and deionized water, and a residue existing on the light emitting element substrate may be removed by using N2. Subsequently, the first insulating film INF1 may be provided on the light emitting stack pattern 10.

Next, in order to form the first insulating film INF1 including A1₂O₃ as an example of the above-described aluminum oxide AlOₓ, a light emitting element substrate on which the light emitting stack pattern 10 is formed may be located in a container. As described above, the container may be a beaker, and the light emitting element substrate may mean a structure including the stack substrate 1, the sacrificial layer 3 formed on the stack substrate 1, and the light emitting stack pattern 10 formed on the sacrificial layer 3. Aluminum isopropoxide as a precursor is provided in the container, 2-methoxyethanol is added, and the aluminum isopropoxide and the 2-methoxyethanol are stirred at a first temperature for a first time. Subsequently, acetylacetone is added, and the acetylacetone and a mixture of the aluminum isopropoxide and the 2-methoxyethanol are stirred at a second temperature for a second time. The second temperature may be higher than the first temperature, and the second time may be greater than the first time. In an example, the first temperature may be about 70° C. to about 90° C., and the second temperature may be about 95° C. to about 115° C. The first time may be about 20 minutes to about 40 minutes, and the second time may be about 110 minutes to about 130 minutes. A chemical reaction in which the precursor is provided as the A1₂O₃ may be performed. Subsequently, the formation of the first insulative layer INF1 may be completed by unloading the light emitting element substrate from the container and heating the unloaded light emitting element substrate.

Referring to FIG. 8, a bonding layer 19 may be connected onto the light emitting stack pattern 10. Although not shown in the drawing, a first metal may be coated on the light emitting stack pattern 10, and a second metal may be coated on a surface of the bonding layer 19, which is to be connected to the light emitting stack pattern 10. Bonding between the first metal and the second metal may be performed under a predetermined temperature and pressure condition, so that the bonding layer 19 and the light emitting stack pattern 10 can be bonded to each other. In accordance with an embodiment, the process of bonding the first metal and the second metal may be performed under a temperature of about 300° C. to about 400° C. and a pressure of about 1 kgf/cm² to about 5 kgf/cm². The first metal may be gold (Au) or tin (Sn). However, the disclosure is not limited thereto, and the first metal may be a single metal or a metal material in which metals are alternately arranged. For example, the first metal may be a metal material in which gold (Au), tin (Sn), and gold (Au) are alternately arranged. A layer made of Au in the first metal may have a thickness of about 500 nm, and a layer made of Sn in the first metal may have a thickness of about 1,000 nm. The second metal may include a material having an improved thermal conductivity. For example, the second metal may include at least one of molybdenum (Mo), copper-graphite (Cu-graphite), and aluminum nitride ceramics (A1N).

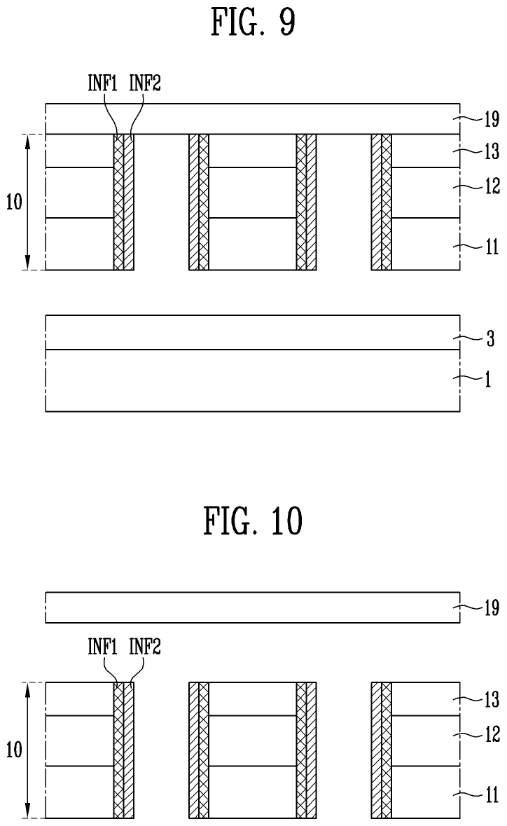

Referring to FIG. 9, the light emitting stack pattern 10 may be separated from the stack substrate 1 and the sacrificial layer 3. In an example, the light emitting stack pattern 10 may be separated by a laser lift-off (LLO) process or a chemical lift-off (CLO) process. The process of physically separating the light emitting stack pattern 10 from the stack substrate 1 and the sacrificial layer 3 may be performed on the first semiconductor layer 11 located between the light emitting stack pattern 10 and the sacrificial layer 3. In case that the light emitting stack pattern 10 is separated, at least a portion of the first semiconductor layer 11, which is not included in the light emitting stack pattern 10, may still remain on the sacrificial layer 3. After the light emitting stack pattern 10 is separated from the stack substrate 1 and the sacrificial layer 3, the light emitting element LD described with reference to FIGS. 1 and 2 may be provided.

Referring to FIG. 10, the bonding layer 19 may be removed. In case that the bonding layer 19 is removed, the light emitting stack pattern 10 having a predetermined shape may be provided. The separated light emitting stack pattern 10 may be in a state in which a surface of the first semiconductor layer 11 and a surface of the second semiconductor layer 13 are exposed to the outside. Subsequently, a process of removing an impurity on the surface of the light emitting stack pattern 10, which is exposed to the outside, may be performed.

In an example, a dry etching process may be performed on the first semiconductor layer 11 of the light emitting stack pattern 10, and an 02 plasma treatment process may be performed on the surface of the first semiconductor layer 11, which is exposed to the outside. Accordingly, the impurity existing on the surface of the first semiconductor layer 11 can be removed. As another example, a dry etching process may be performed on the first semiconductor layer 11 of the light emitting stack pattern 10, and at least a portion of the first semiconductor layer 11 may be removed by a wet etching process. Accordingly, the concentration of the impurity remaining on the surface of the first semiconductor layer 11 can be decreased. A KOH or NaOH solution may be used for the wet etching process.

After the light emitting stack pattern 10 is separated from the stack substrate 1 and the sacrificial layer 3, and the bonding layer 19 is removed, the light emitting element LD described with reference to FIGS. 1 and 2 may be provided.

Subsequently, the light emitting element LD provided as the light emitting stack pattern 10 is dispersed in a solvent, so that an ink including the light emitting element LD and the solvent can be prepared.

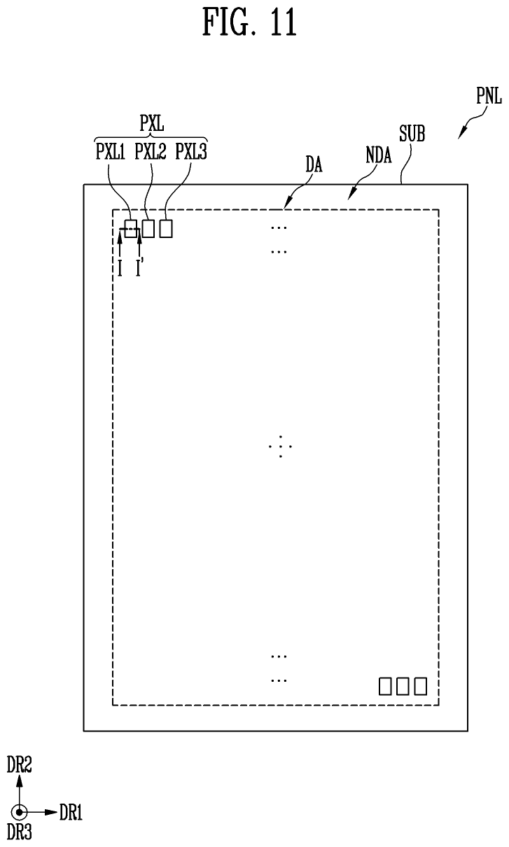

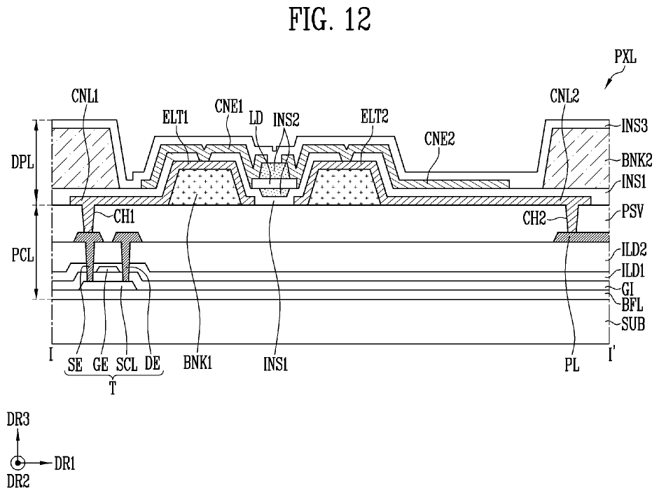

Hereinafter, a display device to which the light emitting element LD is applied in accordance with an embodiment will be described with reference to FIGS. 11 and 12.

FIG. 11 is a schematic plan view illustrating a display device including the light emitting element in accordance with an embodiment.

FIG. 11 illustrates a display device, specifically, a display panel PNL provided in the display device, as an example of an electronic device which can use the light emitting element LD as a light source. FIG. 11 schematically illustrates a structure of the display panel PNL

SD-210337-SKB 16 with respect to a display area DA. However, in some embodiments, at least one driving circuit (e.g., at least one of a scan driver and a data driver), lines, and/or pads, which are not shown in the drawing, may be further disposed in the display panel PNL.

Referring to FIG. 11, the display panel PNL may include a substrate SUB and a pixel PXL disposed on the substrate SUB. Pixels PXL may be provided on the substrate SUB.

The substrate SUB forms a base member of the display panel PNL and may be a rigid or flexible substrate or film.

The display panel PNL and the substrate SUB for forming the same may include the display area DA for displaying an image and a non-display area NDA adjacent to the display area DA.

Pixels PXL may be arranged in the display area DA. The pixel PXL may include the light emitting element LD. Various lines, pads, and/or a built-in circuit, which are electrically connected to the pixels PXL of the display area DA, may be disposed in the non-display area NDA. The pixels PXL may be regularly arranged in the display area DA according to a stripe structure, a PenTile® structure, or the like. However, the arrangement structure of the pixels PXL is not limited thereto, and the pixels PXL may be arranged in the display area DA by using various structures and/or methods.

In some embodiments, two or more kinds of pixels PXL emitting light of different colors may be disposed in the display area DA. In an example, the pixel PXL may include a first pixel PXL1 emitting light of a first color, a second pixel PXL2 emitting light of a second color, and a third pixel PXL3 emitting light of a third color. At least one first pixel PXL1, a least one second pixel PXL2, and at least one third pixel PXL3, which are disposed adjacent to each other, may constitute a pixel part capable of emitting light of various colors. For example, each of the first to third pixels PXL1, PXL2, and PXL3 may be a sub-pixel emitting light of a predetermined color. In some embodiments, the first pixel PXL1 may be a red pixel emitting light of red, the second pixel PXL2 may be a green pixel emitting light of green, and the third pixel PXL3 may be a blue pixel emitting light of blue. However, the disclosure is not limited thereto.

In an embodiment, the first pixel PXL1, the second pixel PXL2, and the third pixel PXL3 respectively have, as light sources, a light emitting element of the first color, a light emitting element of the second color, and a light emitting element of the third color, so that the light emitting elements can respectively emit light of the first color, the second color, and the third color. In an embodiment, the first pixel PXL1, the second pixel PXL2, and the third pixel PXL3 have light emitting elements emitting light of a same color and may include color conversion layers and/or color filters of different colors, which are disposed on the respective light emitting elements, to respectively emit light of the first color, the second color, and the third color. However, the color, kind, and/or number of pixels PXL constituting each pixel part is not particularly limited. For example, the color of light emitted from each pixel PXL may be variously changed.

The pixel PXL may include at least one light source driven by a predetermined control signal (e.g., a scan signal and a data signal) and/or a predetermined power source (e.g., a first power source and a second power source). In an embodiment, each pixel PXL may be configured as an active pixel. However, the kind, structure, and/or driving method of pixels PXL which can be applied to the display device are not particularly limited. For example, each pixel PXL may be configured as a pixel of a passive or active light emitting display device using various structures and/or driving methods.

FIG. 12 is a schematic cross-sectional view taken along line I-I′ shown in FIG. 11.

Referring to FIG. 12, the pixel PXL may include the substrate SUB, a pixel circuit part PCL, and a display element part DPL.

The substrate SUB may be a rigid or flexible substrate. In an example, the substrate SUB may include a rigid material or a flexible material. In an example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, cellulose triacetate, and cellulose acetate propionate. However, the material of the substrate SUB, which is used in the embodiment of the disclosure, is not limited to a specific example.

The pixel circuit part PCL may be located on the substrate SUB. The pixel circuit part PCL may include a buffer layer BFL, a transistor T, a gate insulating layer GI, a first interlayer insulating layer ILD1, a second interlayer insulating layer ILD2, a first contact hole CH1, a second contact hole CH2, and a protective layer PSV.

The buffer layer BFL may be located on the substrate SUB. The buffer layer BFL may prevent an impurity from being diffused from the outside. The buffer layer BFL may include at least one of silicon nitride (SiNₓ), silicon oxide (SiOₓ), silicon oxynitride (SiOxNy), and metal oxide such as aluminum oxide (AlOx).

The transistor T may be a driving transistor. The transistor T may include a semiconductor layer SCL, a gate electrode GE, a source electrode SE, and a drain electrode DE.

The semiconductor layer SCL may be located on the buffer layer BFL. The semiconductor layer SCL may include at least one of polysilicon, amorphous silicon, and an oxide semiconductor.

The semiconductor layer SCL may include a first contact region contacting the source electrode SE and a second contact region contact the drain electrode DE.

The first contact region and the second contact region may correspond to a semiconductor pattern doped with an impurity. A region between the first contact region and the second contact region may be a channel region. The channel region may correspond to an intrinsic semiconductor pattern not doped with an impurity.

The gate insulating layer GI may be provided over the semiconductor layer SCL. The gate insulating layer GI may include an inorganic material. In an example, the gate insulating layer GI may include at least one of silicon nitride (SiNₓ), silicon oxide (SiOₓ), silicon oxynitride (SiOxN_{y}), and aluminum oxide (A1Oₓ). In some embodiments, the gate insulating layer GI may include an organic material.

The gate electrode GE may be located on the gate insulating layer GI. A position of the gate electrode GE may correspond to that of the channel region of the semiconductor layer SCL. For example, the gate electrode GE may be disposed on the channel region of the semiconductor layer SCL with the gate insulating layer GI interposed therebetween.

The first interlayer insulating layer ILD1 may be located over the gate electrode GE. Similar to the gate insulating layer GI, the first interlayer insulating layer ILD1 may include at least one of silicon nitride (SiNₓ), silicon oxide (SiOₓ), silicon oxynitride (SiOxN_{y}), and aluminum oxide (AlOₓ).

The source electrode SE and the drain electrode DE may be located on the first interlayer insulating layer ILD1. The source electrode SE may electrically contact the first contact region of the semiconductor layer SCL by penetrating the gate insulating layer GI and the first interlayer insulating layer ILD1, and the drain electrode DE may electrically contact the second contact region of the semiconductor layer SCL by penetrating the gate insulating layer GI and the first interlayer insulating layer ILD1. The source electrode SE may be electrically connected to a first electrode ELT1 through the first contact hole CH1.

The second interlayer insulating layer ILD2 may be located over the source electrode SE and the drain electrode DE. Similar to the first interlayer insulating layer ILD1 and the gate insulating layer GI, the second interlayer insulating layer ILD2 may include an inorganic material. The inorganic material may include at least one of the materials forming the first interlayer insulating layer ILD1 and the gate insulating layer GI, e.g., silicon nitride (SiNₓ), silicon oxide (SiOₓ), silicon oxynitride (SiOₓN_{y}), and aluminum oxide (AlOₓ). In some embodiments, the second interlayer insulating layer ILD2 may include an organic material.

A power line PL may be disposed on the second interlayer insulating layer ILD2. The power line PL may be electrically connected to a second connection line CNL2 through the second contact hole CH2. The power line PL may be supplied with power, and the supplied power may be provided to the second connection line CNL2 through the second contact hole CH2.

The protective layer PSV may be located on the second interlayer insulating layer ILD2. The protective layer PSV may cover (or overlap) the power line PL. The protective layer PSV may include an organic insulating layer, an inorganic insulating layer, or an organic insulating layer disposed on an inorganic insulating layer.

The first contact hole CH1, through which the source electrode SE is electrically connected to the first electrode ELT1, and the second contact hole CH2, through which the power line PL is electrically connected to the second electrode ELT2, may be formed in the protective layer PSV.

The display element part DPL may include a first bank BNK1, a first electrode ELT1, a second electrode ELT2, a first insulating layer INS1, a light emitting element LD, a first contact electrode CNE1, a second contact electrode CNE2, a second insulating layer INS2, a second bank BNK2, and a third insulating layer INS3.

The first bank BNK1 may have a shape protruding upwardly, and the first electrode ELT1 and the second electrode ELT2 may be arranged on the first bank BNK1 to form a reflective partition wall. The reflective partition wall is formed, so that the light efficiency of the light emitting element LD can be improved.

A portion of the first electrode ELT1 may be arranged on the protective layer PSV, and another portion of the first electrode ELT1 may be arranged on the first bank BNK1. The first electrode ELT1 may be a path through which electrical information on the light emitting element LD, which is applied through a first connection line CNL1, can be provided. A portion of the second electrode ELT2 may be arranged on the protective layer PSV, and another portion of the second electrode ELT2 may be arranged on the first bank BNK1. The second electrode ELT2 may be a path through which electrical information on the light emitting element LD, which is applied through the second connection line CNL2, can be provided.

The first insulating layer INS1 may be located on the protective layer PSV. Similar to the second interlayer insulating layer ILD2, the first insulating layer INS1 may include at least one of silicon nitride (SiNₓ), silicon oxide (SiOₓ), silicon oxynitride (SiOₓN_{y}), and aluminum oxide (AlOₓ).

At least a portion of the first insulating layer INS1 may be disposed on the first contact electrode CNE1, the second contact electrode CNE2, the first electrode ELT1, and/or the second electrode ELT2 to stabilize electrical connection and reduce an external influence.

The light emitting element LD may be located on the first insulating layer INS1. In an example, the first insulating layer INS1 may have a groove, at least a portion of the light emitting element LD may contact an end portion formed from the groove, and another end portion of the light emitting element LD may contact another end portion formed from the groove.

The light emitting element LD may be located on the first insulating layer INS1 between the first electrode ELT1 and the second electrode ELT2. The light emitting element LD may be the light emitting element LD described above with reference to FIGS. 1 and 2.

The second insulating layer INS2 may be located on the light emitting element LD.

The second insulating layer INS2 may cover (or overlap) an area corresponding to the active layer 12 of the light emitting element LD. The second insulating layer INS2 may include at least one of an organic material and an inorganic material.

In some embodiments, at least a portion of the second insulating layer INS2 may be located on a rear surface of the light emitting element LD. The second insulating layer INS2 formed on the rear surface of the light emitting element LD may fill a gap between the first insulating layer INS1 and the light emitting element LD in a process of forming the second insulating layer INS2 on the light emitting element LD.

The first contact electrode CNE1 and the second contact electrode CNE2 may be located on the first insulating layer INS1. The first contact electrode CNE1 and the second contact electrode CNE2 may be electrically connected respectively to the first electrode ELT1 and the second electrode ELT2 through a contact hole formed in the first insulating layer INS1.

The first contact electrode CNE1 and the second contact electrode CNE2 may include at least one of conductive materials including indium tin oxide (ITO), indium zinc oxide (IZO), and indium tin zinc oxide (ITZO).

An electrical signal provided through the first electrode ELT1 may be provided to the light emitting element LD through the first contact electrode CNE1. The light emitting element LD may emit light in response to the provided electrical signal. An electrical signal provided through the second electrode ELT2 may be provided to the light emitting element LD through the second contact electrode CNE2.

The second bank BNK2 may be a structure defining an emission area of the pixel PXL. The emission area may mean an area in which light is emitted from the light emitting element LD. For example, the second bank BNK2 may be disposed in a boundary area between adjacent light emitting elements LD to surround the light emitting element LD of the pixel PXL.

The third insulating layer INS3 may be arranged on the second bank BNK2, the first contact electrode CNE1, the second contact electrode CNE2, and the second insulating layer INS2. The third insulating layer INS3 may include at least one of an organic material and an inorganic material. The third insulating layer INS3 may protect the display element part

DPL from an external influence.

The arrangement of the light emitting element LD, the electrodes, and the like is not limited to the example described with reference to FIG. 12, and arrangement in accordance with various modifiable embodiments may be implemented.

Hereinafter, an improved technical effect of the light emitting element LD in accordance with the disclosure will be described in detail by comparing light emitting elements LD in accordance with embodiments with light emitting elements in accordance with comparative examples.

### Embodiments

Light emitting elements LD in accordance with embodiments 1 to 12 were manufactured as shown in the following Table 1.

In the light emitting elements LD in accordance with embodiments 1 to 4, the first insulating film INF1 was formed by a dry process, and the second insulating film INF2 was formed by a wet process.

In the light emitting elements LD in accordance with embodiments 5 to 8, the first insulating film INF1 was formed by a wet process, and the second insulating film INF2 was formed by a dry process.

In the light emitting elements LD in accordance with embodiments 9 to 12, the first insulating film INF1 was formed by a wet process, and the second insulating film INF2 was formed by a wet process.

A material included in each of the first insulating film INF1 and the second insulating film INF2 and a thickness of each of the first insulating film INF1 and the second insulating film INF2 are shown in Table 1.

TABLE 1

| Classification | First insulating film (INF1) | Second insulating film (INF2) |
|---|---|---|
| Embodiment 1 | SiO₂, 10 nm, Dry process | Al₂O₃, 40 nm, Wet process |
| Embodiment 2 | SiO₂, 10 nm, Dry process | SiO₂, 40 nm, Wet process |
| Embodiment 3 | Al₂O₃, 10 nm, Dry process | Al₂O₃, 40 nm, Wet process |
| Embodiment 4 | Al₂O₃, 10 nm, Dry process | SiO₂, 40 nm, Wet process |
| Embodiment 5 | SiO₂, 40 nm, Wet process | Al₂O₃, 40 nm, Dry process |
| Embodiment 6 | SiO₂, 40 nm, Wet process | SiO₂, 40 nm, Dry process |
| Embodiment 7 | Al₂O₃, 40 nm, Wet process | Al₂O₃, 40 nm, Dry process |
| Embodiment 8 | Al₂O₃, 40 nm, Wet process | SiO₂, 40 nm, Dry process |
| Embodiment 9 | SiO₂, 40 nm, Wet process | Al₂O₃, 40 nm, Wet process |
| Embodiment 10 | SiO₂, 40 nm, Wet process | SiO₂, 40 nm, Wet process |
| Embodiment 11 | Al₂O₃, 40 nm, Wet process | Al₂O₃, 40 nm, Wet process |
| Embodiment 12 | Al₂O₃, 40 nm, Wet process | SiO₂, 40 nm, Wet process |

### Comparative Examples

Light emitting elements in accordance with comparative examples 1 to 6 were manufactured as shown in the following Table 2.

The light emitting element in accordance with each comparative example includes an inner insulating film and an outer insulating film. The inner insulating film corresponds to the first insulating film INF1 of the disclosure, and the outer insulating film corresponds to the second insulating film INF2 of the disclosure.

Each of the inner insulating film and the outer insulating film, which are included in each of the light emitting elements in accordance with comparative examples 1 to 4, was formed by a dry process.

The inner insulating film included in each of the light emitting elements in accordance with comparative examples 5 and 6 was formed by a wet process, and the outer insulating film included in each of the light emitting elements in accordance with comparative examples 5 and 6 was formed by a dry process.

A thickness of each of the insulating films included in the light emitting elements in accordance with the comparative examples and a material included in each of the insulating films included in the light emitting elements in accordance with the comparative examples are shown in the following Table 2.

TABLE 2

| Classification | Inner insulating film | Outer insulating film |
|---|---|---|
| Comparative Example 1 | SiO₂, 40 nm, Dry process | Al₂O₃, 40 nm, Dry process |
| Comparative Example 2 | Al₂O₃, 40 nm, Dry process | SiO₂, 40 nm, Dry process |
| Comparative Example 3 | ZnO, 40 nm, Dry process | Al₂O₃, 40 nm, Dry process |
| Comparative Example 4 | ZnO, 40 nm, Dry process | SiO₂, 40 nm, Dry process |
| Comparative Example 5 | ZnO, 40 nm, Wet process | Al₂O₃, 40 nm, Dry process |
| Comparative Example 6 | ZnO, 40 nm, Wet process | SiO₂, 40 nm, Dry process |

### Experimental Examples

Experiments were performed so as to check light emitting characteristics of the light emitting elements manufactured in accordance with embodiments 1 to 12 and comparative examples 1 to 6.

In case that light is provided from the light emitting element in accordance with each embodiment or each comparative example, intensities of the provided light in a wavelength band of about 445 nm and a wavelength band of about 560 nm were measured. The light intensity measurement was performed by using a Cary Eclipse fluorescence spectrophotometer (Varian, Inc., Australia). Data about each wavelength band was expressed as a relative intensity.

TABLE 3

| Classification | 445 nm | 560 nm |
|---|---|---|
| Embodiment 1 | 32 | 0.52 |
| Embodiment 2 | 31 | 0.57 |
| Embodiment 3 | 35 | 0.58 |
| Embodiment 4 | 38 | 0.54 |
| Embodiment 5 | 55 | 0.49 |
| Embodiment 6 | 58 | 0.57 |
| Embodiment 7 | 47 | 0.52 |
| Embodiment 8 | 45 | 0.53 |
| Embodiment 9 | 65 | 0.57 |
| Embodiment 10 | 57 | 0.55 |
| Embodiment 11 | 52 | 0.59 |
| Embodiment 12 | 48 | 0.48 |
| Comparative Example 1 | 1 | 1 |
| Comparative Example 2 | 1.05 | 0.92 |
| Comparative Example 3 | 1.03 | 0.95 |
| Comparative Example 4 | 1.07 | 0.93 |
| Comparative Example 5 | 21 | 0.98 |
| Comparative Example 6 | 23 | 0.97 |

Referring to Table 3, it can be seen that intensities of light emitted by the light emitting elements LD in accordance with embodiments 1 to 12 in a wavelength band of about 445 nm are greater than those of light emitted from the light emitting elements in accordance with comparative examples 1 to 6 in a wavelength band of about 445 nm. The light in a wavelength band of about 445 nm means blue light, and the intensity of the blue light emitted from the light emitting element LD preferably become larger. For example, as an experimental result, it can be seen that the light emitting elements LD in accordance with the embodiments have improved light emitting efficiency of the blue light, as compared with the light emitting elements in accordance with the comparative examples.

It can be seen that intensities of light emitted from the light emitting elements LD in accordance with embodiments 1 to 12 in a wavelength band of about 560 nm are smaller than those of light emitted from the light emitting elements in accordance with comparative examples 1 to 6 in a wavelength band of about 560 nm.

In case that a gallium-based material (e.g., GaN) is included in the light emitting element LD, light having a wavelength in the wavelength band of about 560 nm may be light provided to the outside when a vacancy is formed as gallium is emitted from a structure (e.g., the first semiconductor layer 11) in the light emitting element LD. For example, a phenomenon in which light having a wavelength in a wavelength band of about 560 nm is intensively output may mean that multiple defects occur due to gallium leakage in the light emitting element LD. For example, as an experimental result, in the light emitting element LD in accordance with each of the embodiments, a small number of gallium vacancies are formed as compared with the light emitting element in accordance with each of the comparative examples, and thus the occurrence of defects in the light emitting element LD in accordance with the embodiments can be reduced.

In accordance with an embodiment, at least one of the insulating films INF of the light emitting element LD may be formed by a wet process. The wet process does not require the supply of a separate precursor, and thus a process of removing a precursor which is not deposited is not required. Thus, there can be provided a manufacturing method for the light emitting element LD, which can reduce process cost. A plasma applying process is not required, and thus there can be provided a manufacturing method for the light emitting element LD, which can prevent damage to the surface of the light emitting element LD.

In accordance with the disclosure, there can be provided a manufacturing method for a light emitting element, a light emitting element manufactured by using the same, and a display device including the same, which can reduce process cost and decrease process performance time.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used separately or in combination with features, characteristics, and/or elements described in connection with other embodiments unless otherwise specifically indicated. Accordingly, it will be understood by those of skill in the art that various changes in form and details may be made without departing from the spirit and scope of the disclosure.

What is claimed is:

1. A method for manufacturing a light emitting element, the method comprising:
forming a first semiconductor layer on a substrate, the first semiconductor layer including a semiconductor of a first type;
forming an active layer on the first semiconductor layer;
forming a second semiconductor layer on the active layer, the second semiconductor layer including a semiconductor of a second type different from the first type;
performing an etching process of removing at least a portion of each of the first semiconductor layer, the active layer, and the second semiconductor layer in a direction toward the first semiconductor layer from the second semiconductor layer; and
forming a first insulating layer to surround an outer surface of the active layer,
wherein the first insulating layer is formed by a wet process.

2. The method of claim 1, wherein the performing of the etching process includes forming a light emitting structure to include:
the first semiconductor layer;
the active layer disposed on the first semiconductor layer; and
the second semiconductor layer disposed on the active layer.

3. The method of claim 2, further comprising forming a sacrificial layer on the substrate after the preparing of the substrate.

4. The method of claim 1, further comprising forming a second insulating layer on the first insulating layer.

5. The method of claim 4, wherein the second insulating layer is formed by a wet process.

6. The method of claim 4, wherein the second insulating layer is formed by a dry process.

7. The method of claim 1, comprising forming a second insulating layer on the active layer by a dry process before the forming of the first insulating layer.

8. The method of claim 1, wherein the wet process is at least one of a sol-gel process, a dip coating process, and an electrochemical deposition process.

9. The method of claim 6, wherein the dry process is at least one of Atomic Layer Deposition (ALD), Physical Vapor Deposition (PVD), Chemical Vapor Deposition (CVD), and Plasma Enhanced Chemical Vapor Deposition (PECVD).

10. The method of claim 1, wherein the first insulating layer includes at least one of silicon oxide (SiOₓ), silicon nitride (SiNₓ), silicon oxynitride (SiON), aluminum oxide (A1Oₓ), and titanium oxide (TiO_{x).}

11. The method of claim 4, wherein the second insulating layer includes at least one of silicon oxide (SiOₓ), silicon nitride (SiNₓ), silicon oxynitride (SiON), aluminum oxide (AlOₓ), and titanium oxide (TiOₓ).

12. The method of claim 1, wherein the first insulating layer has a thickness in a range of about 5 nm to about 200 nm.

13. The method of claim 12, wherein the first insulating layer has a thickness in a range of about 35 nm to about 45 nm.

14. The method of claim 4, wherein the second insulating layer has a thickness in a range of about 35 nm to about 45 nm.

15. A light emitting element comprising:
a substrate;
a first semiconductor layer disposed on the substrate and including a semiconductor of a first type;
an active layer disposed on the first semiconductor layer;
a second semiconductor layer disposed on the active layer and including a semiconductor of a second type different from the first type;
a first insulating layer surrounding an outer surface of the active layer and formed by using a wet process; and
forming a second insulating layer on the first insulating layer and formed by using a wet process,
wherein at least a portion of each of the first semiconductor layer, the active layer, and the second semiconductor layer is removed by an etching process in a direction toward the first semiconductor layer from the second semiconductor layer

16. The light emitting element of claim 15, wherein
the first insulating layer includes silicon oxide (SiOₓ), and
the second insulating layer includes aluminum oxide (AlOₓ).

17. The light emitting element of claim 16, wherein
the first insulating layer has a thickness in a range of about 35 nm to about 45 nm, and
the second insulating layer has a thickness in a range of about 35 nm to about 45 nm.

18. A display device comprising a light emitting element manufactured by using the method of claim 1.

19. A light emitting element comprising:
a first semiconductor layer including a semiconductor of a first type;
a second semiconductor layer including a semiconductor of a second type different from the first type;
an active layer disposed between the first semiconductor layer and the second semiconductor layer; and
a first insulating layer surrounding an outer surface of at least the active layer,
wherein the first insulating layer includes at least one of silicon oxide (SiOₓ) and aluminum oxide (AlOₓ).

20. The light emitting element of claim 19, further comprising a second insulating layer arranged on the first insulating layer, the second insulating layer surrounding the outer surface of the active layer,
wherein the second insulating layer includes at least one of silicon oxide (SiOₓ) and aluminum oxide (AlOₓ).
